(19) United States
(12) Patent Application Publication
(10) Pub. No.: US 2006/0267595 A1
(43) Pub. Date: Nov. 30, 2006

(54) Electrical component with fractional order impedance

(75) Inventors: Gary W. Bohannan, Bozeman, MT (US); Stephanie K. Hurst, Bozeman, MT (US); Lee Spangler, Bozeman, MT (US)

Correspondence Address: MORGAN LEWIS & BOCKIUS LLP, 1111 PENNSYLVANIA AVENUE NW, WASHINGTON, DC, 20004, US

(73) Assignees: Wavelength Electronics, Inc.; Montana State University

(21) Appl. No.: 11/372,232

(22) Filed: Mar. 10, 2006

Related U.S. Application Data
(60) Provisional application No. 60/660,325, filed on Mar. 11, 2005.

(51) Int. Cl. G01R 27/00

(52) U.S. Cl. 324/600

(57) ABSTRACT

An electrical component and material with fractional order impedance, as well as electrical circuits for use in fractional order calculus for automated signal processing are provided. Fractional order methods can be particularly important in solving nonlinear problems, such as performing automatic control, pattern recognition, system characterization, signal processing, and modeling.

### CROSS-REFERENCE TO RELATED APPLICATIONS

This application claims the benefit of U.S. Provisional application 60/660,325, filed on Mar. 11, 2005.

### STATEMENT REGARDING FEDERALLY SPONSORED RESEARCH OR DEVELOPMENT

Not applicable

### INCORPORATION-BY-REFERENCE OF MATERIAL SUBMITTED ON A COMPACT DISC

Not applicable

### SEQUENCE LISTING

Not applicable

### FIELD OF THE INVENTION

The present invention relates to electrical circuits for signal processing, such as for system control, characterization or modeling. More particularly, the invention relates to electrical components that have fractional order (FO) impedances, their methods of manufacture, and their use in signal processing.

### BACKGROUND OF THE INVENTION

Generally, electrical components can be used to perform analog, real time calculus operations for scientific or engineering applications. More specifically, electrical components with FO impedances can be used to perform FO calculus operations, which are particularly important in many applications.

Impedance is defined as the ratio of the voltage across a device to the current through the device. In alternating current (ac) systems, it is defined as the ratio of the amplitudes of the voltage and current along with the phase lead or lag between the two.

Standard electrical components include resistors, capacitors, and inductors. Each component has some characteristics that are time-related and some that are important overall. A resistor is a simple component that creates an electrical voltage across its terminals that is proportional to the electrical current that passes through it. If the applied voltage changes, the current responds substantially immediately, without significant delay or lag in time. Overall, the resistor's terminal voltage can induce a voltage loss in a circuit. Additionally, a resistor dissipates energy equal to its instantaneous voltage times its current.

A capacitor also has time-related and overall characteristics. In relation to time, when a voltage is newly applied, a capacitor initially does not respond with a new terminal voltage but retains the original. It then slowly responds, conforming the terminal voltage to the applied voltage over a response period. In an alternating current (AC) system, a capacitor's current leads its voltage by one-quarter cycle, a phase shift of +90 degrees. Overall, the ideal capacitor alternates between storing energy from a circuit during one period and discharging it back into the circuit during the next. Ideally, it dissipates no energy.

An inductor, is similar to a capacitor, except that it responds over time to a change in applied current, rather than a change in applied voltage. Like a capacitor, it ideally stores and then releases energy rather than dissipating it. In an alternating current (AC) system, an inductor's current lags its voltage by one-quarter cycle, a phase shift of −90 degrees. Standard electrical components perform within their respective categories, such as resistors, capacitors or inductors, and have no significant mixing of characteristics. They are considered to have integer-order impedances.

However, electrical components need not be limited to the separate characteristics of ideal resistors, capacitors or inductors. It would be useful if components had characteristics that were somewhere between the characteristics of standard components. A component may have characteristics, such as a fractional order electrical impedance, that are between the characteristics of a resistor and a capacitor. For example, the characteristics could be a combination of some of the immediate, current-based response and voltage loss of a resistor with some of the time-delayed response to changes in voltage seen in capacitors.

In general, the impedance of an electrical component can be expressed as a Laplace transfer function that is proportional to s^{-α}, where α is a number that describes the characteristics of the component. The phase shift between a device's current and its voltage is incorporated in the exponent. The phase shift, in degrees, is given by φ=−α*90. Specifically, the impedance of a standard resistor, R, can be expressed as R*s^{-α}, with α equal to zero. The impedance of an ideal capacitor is proportional to s⁻¹. The impedance of an ideal inductor is proportional to s¹. Such impedances are of integer-order.

Ideal resistors, capacitors or inductors have α's exactly equal to 0, 1, or −1, respectively. However, actual electrical components do not have exactly integer α values. Very high quality capacitors, such as those made from polypropylene or polystyrene, have α values of 0.999 to 0.9999 or better. (See, e.g., Westerlund, et al, “Capacitor Theory,” in IEEE Trans. on Dielectrics and Electrical Insulation, 1 (1994) 5.). Even poor resistors, capacitors and inductors have α's within 5% of their ideal integer values.

Fractional order impedance can be approximated from a network of standard (integer-order impedance) components. For example, Newton approximations of impedances with α's of −½, ½, ⅓ and ¼ can be implemented using networks of resistors, capacitors and inductors, as reported by Carlson et al. in IEEE Tran. on Circuits and Systems 7 (1964) 210. Similarly, the combination of a battery, circuit terminals that connect to the battery, and corrosion between the battery terminals and the circuit terminals, can have an impedance with an α near ½ at very long time scales. Combinations like this are referred to as Warburg impedances.

In contrast to standard components with substantially integer-order impedances or combinations of components that form noninteger-order impedances, it would be useful to have a single electrical component with a non-integer value of α, giving a fractional order impedance and a phase shift that is not restricted to the values of −90, 0 or +90 degrees. For example, a component could have characteristics between those of a resistor and a capacitor, such as an exemplary α of −0.7. This would give the electrical designer more options in selecting the phase and energy storage/dissipation relationships for a particular need. Such fractional order components could be used to implement electrical circuits and methods that are not conventionally available.

Conventional calculus methods have been used to solve important problems for scientists, engineers, and consumers. An example is the PID controller circuit that is commonly used for automated control, such as for control of electrical motors or electrical heaters. Conventional calculus uses differentiation and integration to discrete, integer orders. For example, first or second derivatives, or first or second integrals, are used. Integer order differentiation may be expressed as having a Laplace transfer function proportional to sⁿ, with n being an integer. Likewise, integer order integration may be expressed by a Laplace transfer function proportional to s⁻ⁿ.

In contrast, fractional order calculus is a generalization of conventional calculus that allows differentiation and integration to fractional order (FO). FO methods can be particularly important in solving nonlinear problems, such as performing automatic control, pattern recognition, system characterization, signal processing, and modeling of biological or chemical processes, vibration, viscoelasticity, damping, chaos, fractals, diffusion, wave propagation, percolation and irreversability. Similar to traditional calculus operations, FO differentiation and integration can be expressed with Laplace transfer functions s^{r} and s^{-r}, respectively. However, with FO calculus, r is any real number, such as a fraction 1/n.

Various methods have been used to perform fractional order calculus operations. Complicated electrical networks that approximate FO impedances (discussed above) have been used to approximate FO calculus operations, as reported by Carlson et al. in IEEE Tran. on Circuits and Systems 7 (1964) 210. Additionally, fractional order calculus operations have been simulated by digitally approximating the problems and calculating approximate solutions. Digital approximations are necessarily limited in bandwidth, highly consumptive of computer resources, and can suffer from numerical instabilities due to finite precision arithmetic. These limitations can make digital techniques impractical or incapable of solving many problems, such as controlling fast processes or “stiff” processes, which involve strong opposing forces.

Fractional order calculus methods can be particularly important in solving scientific or engineering problems. However, digital approximations to implementation of FO transfer functions have important limitations that may render digital techniques impractical or incapable of solving many problems. Analog approximations require extensive networks of components to approximate the needed FO impedances. Thus, there is a need for a single electrical component with fractional order impedance, which can be used to simply implement FO calculus operations or for other uses.

### SUMMARY OF THE INVENTION

In one embodiment, the present invention provides an electrical component that has a fractional order impedance.

In another embodiment, the present invention provides a material that has a fractional order impedance.

In another embodiment, the present invention provides a partially oxidized platinum complex of Formula (III):
[A]ₓ[Pt(L)_{b}Z_{y}] (III)
wherein

A is an aromatic cation;

L is a ligand selected from the group consisting of oxalate, cyano;

Z is an anion;

x is 1, 2 or a non-integer between 1 and 2;

b is an integer 1-4; and

y is 0 or a non-integer between 0 and 2

and all hydrates thereof.

In another embodiment, the invention provides a composite material comprising the combination of at least one host and at least one partially oxidized platinum complex of formula IV:
[A]ₓ[Pt(L)_{b}Z_{y}] (IV)
wherein

A is a cation;

L is a ligand selected from the group consisting of oxalate, cyano;

Z is an anion;

x is 1, 2 or a non-integer between 1 and 2;

b is an integer 1-4; and y is 0 or a non-integer between 0 and 2,

and all hydrates thereof, and wherein the host is selected from the group consisting of a polymer, a copolymer, and combinations thereof.

In a preferred embodiment, the invention provides composite material comprising the combination of a host and a partially oxidized platinum complex of formula III, wherein the host is selected from the group consisting of a polymer, a copolymer, and combinations thereof.

In another embodiment, the invention provides composite material comprising the combination of a host and a partially oxidized platinum complex of formula III, wherein the host includes sol-gel material.

In another embodiment, the present invention provides a method for making an electrical component that has a fractional order impedance.

In another embodiment, the present invention provides an electrical circuit that implements a fractional order calculus operation.

In another embodiment, the present invention provides an automatic control circuit that uses an electrical component that has a fractional order impedance.

The foregoing general description and the following detailed description are merely exemplary and explanatory and are not restrictive of the invention as claimed.

### BRIEF DESCRIPTION OF THE DRAWINGS

The accompanying drawings, which are incorporated in and constitute a part of this specification, illustrate exemplary embodiments of the invention and, together with the description, serve to explain the principles of the invention. In the drawings:

FIG. 1A schematically shows an exemplary electrical component that has a fractional order electrical impedance, in accordance with the present invention.

FIG. 1B schematically shows an alternative, exemplary electrical component that has a fractional order electrical impedance and is shaped into a long ribbon of FO material, in accordance with the present invention.

FIG. 1C schematically shows an alternative, exemplary electrical component that has a fractional order electrical impedance and is shaped into a thin film of FO material, in accordance with the present invention.

FIG. 2 is a graph of the magnitude and phase of electrical impedance of a complex of [NH₂Bu₂]ₓ[Pt(Ox)₂] nanowires in a PVA/Pani copolyer measured from 10 Hz to 300 KHz.

FIG. 3 shows two SEM images of chemically grown [C₁₀H₁₀N]ₓ[Pt(Ox)₂] nanowires.

FIG. 4 shows three TEM images of chemically grown [C₁₀H₁₀N]ₓ[Pt(Ox)₂] nanowires, and one electron diffraction pattern of such nanowires.

FIG. 5 shows an EDS spectrum of electrochemically grown [C₁₀H₁₀N]ₓ[Pt(Ox)₂] nanowires.

FIGS. 6A and 6B are graphs showing exemplary material/device performance curves of a component with fractional order impedance in accordance with the present invention.

FIG. 7 schematically shows an exemplary electrical circuit for a low pass filter having a fractional order impedance component according to the present invention.

FIG. 8 schematically shows an exemplary electrical circuit for using fractional order electrical impedance to perform fractional order integration in accordance with the present invention.

FIG. 9 schematically shows another embodiment of the present invention which is an exemplary automatic controller that uses fractional order electrical impedance.

FIGS. 10 to 14 are schematic diagrams showing additional exemplary electrical circuits using fractor order impedance components.

FIGS. 15A and 15B show a comparison of an exemplary temperature control performance between PI^{λ} using a fractal order integral and conventional PI achieved by replacing the integrator capacitor with a fractor.

FIGS. 16A and 16B show a performance of a fractor having an alternative configuration.

### DETAILED DESCRIPTION OF THE INVENTION

Reference will now be made in detail to the present exemplary embodiments of the invention illustrated in the accompanying drawings. Whenever possible, the same reference numbers will be used throughout the drawings to refer to the same or like parts. Also, where the different embodiments have similar structures, the same reference numbers are usually used.

The present invention is particularly useful for use in analog circuits for performing FO calculus operations for scientific and engineering applications, such as automatic control, system characterization or system modeling. The present invention includes an electrical component with a fractional impedance, its methods of manufacture and it use.

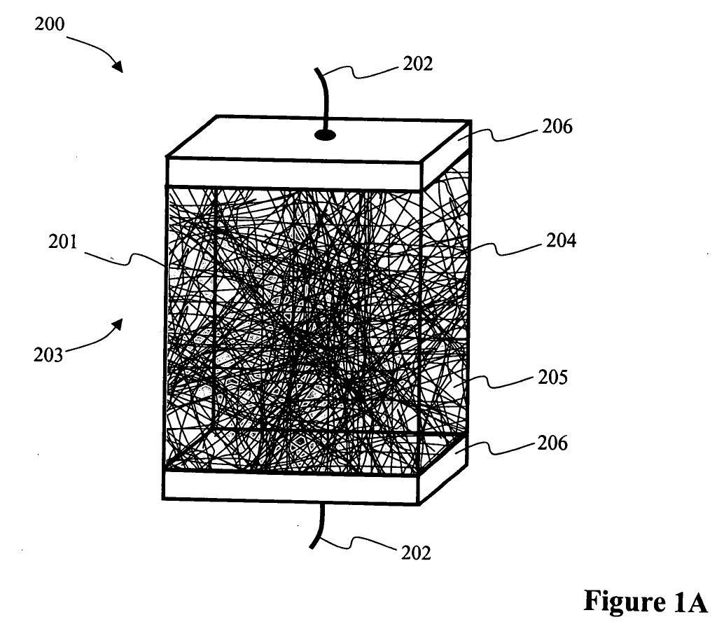

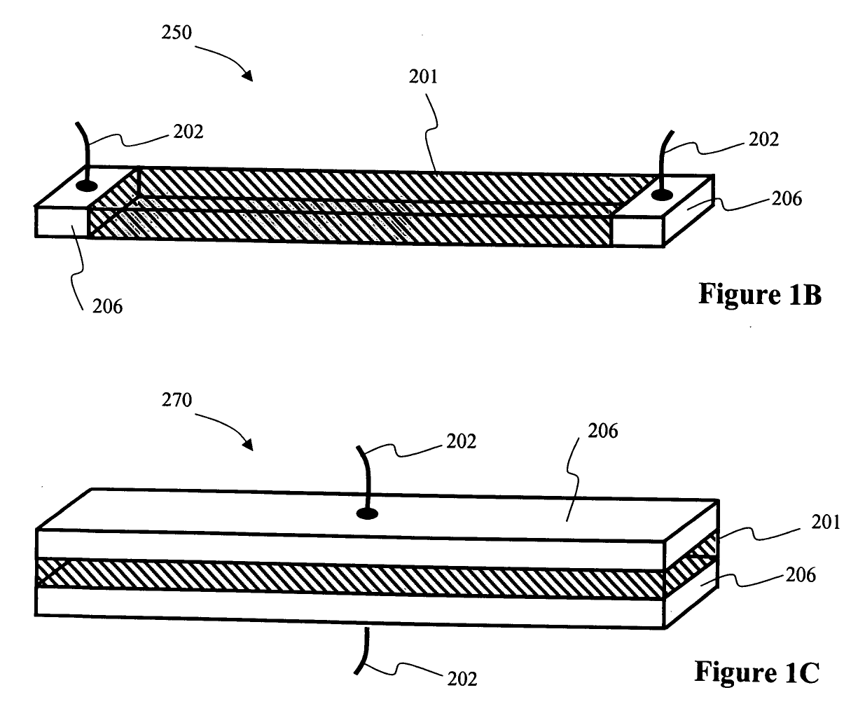

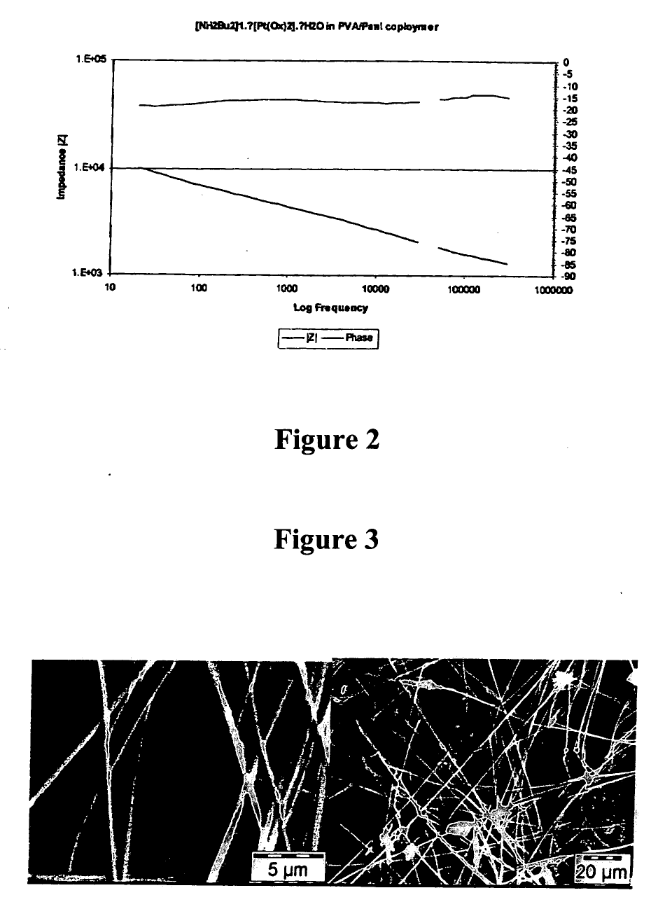

FIG. 1A schematically shows an electrical component 200 that has a fractional order (FO) electrical impedance, in accordance with the present invention. FO component 200 has an FO material 201 and two component terminals 202 electrically connected to parts of the FO material 201. The connection to parts of the FO material may be made through electrically conductive materials 206 or through any other means convenient to electrical connection. FO material 201 includes a complex 203 of nanowires 204. As an example, complex 203 is shown in FIG. 2 to be a three-dimensional complex of nanowires, but complex 203 may be any structure convenient to producing an FO impedance, such as a two-dimensional complex.

The nanowires 204 are electrically conductive, either with only insignificant electrical resistance or with desired electrical resistances. For example, the nanowires 204 may be made of metal-metal polymer chains or of any other material convenient to creating nanowires of desired conductivity or resistance. The polymer chains may be one-dimensional and may be formed of a partially oxidized metal complex, such as a partially oxidized platinum complex. The partial oxidization may be done through any convenient method, such as photo-oxidation. The complex 203 may include some nanowires that touch each other, but, over the complex 203, the nanowires 204 may be prepared so as to reduce bundling of individual wires. Bundling may be reduced by using large cations that force individual wires apart and allow individual atomic wires to be isolated. Furthermore, cations having any structure that allows for formation of the nanowire complex may be used. For example, the cations may potentially be chiral in structure.

The nanowires 204 are encapsulated in a host material 205. The host material 205 may have a specific conductivity, including being non-conductive. For example, the host material 205 may be a polymer, a co-polymer, or any mixture thereof. It may also have any material density or form, such as a solid, liquid, gel, or sol-gel, that is convenient for retaining the complex 203's wire-to-wire spacing and orientation, so as to retain a desired fractional order impedance. Alternatively, as discussed below, some nanowires 204 may be only partially encapsulated by the host material 205 so as to provide electrical contact with the complex 203.

Some parts of the complex 203 may be electrically connected to component terminals 202. For example, some nanowires 204 may extend into a volume of electrically conductive material 206 so as to allow for conveniently forming electrical connection between a part of the complex 203 and a component terminal 202. A second component terminal 202 may be similarly connected to a volume of conductive material 206 and a part of the complex 203.

The nanowires 204 may be randomly oriented, as shown schematically in FIG. 2, or they may be arranged in a preferred orientation. The nanowires 204 may be substantially homogeneous in size and spacing in the complex 203. Alternatively, the nanowires 204 may have a distribution of sizes and spacings. In either case, the FO material 201 may be substantially homogeneous, in that the sizes and spacings of nanowires 204 are interspersed throughout the complex 203 substantially homogeneously. Alternatively, FO material 201 may be inhomogeneous, in that nanowires 204 may have a specific variation in either size or spacing in the complex 203.

FIG. 1B schematically shows an alternative embodiment of the FO component 200, in accordance with the present invention. In this embodiment the FO material 201 is shaped into a ribbon with component terminals 202 connected at each end. Alternatively, FIG. 1C schematically shows an alternative embodiment of the FO component 200 in which the FO material 201 shaped into a thin film with component terminals 202 connected on each face of the film. The FO components of FIGS. 1A-1C are merely exemplary, and the FO component 200 may be formed into any shape convenient for providing a fractional order impedance.

Electrical signals may be conducted through an FO electrical component 200 like that in FIG. 1A, such as from one component terminal 202, through FO material 201, to another component terminal 202. Electrical conduction through FO material 201 causes electrical current to flow down various paths. For example, conduction can be along nanowires 204 and across gaps between nanowires 204. Each path through FO material 201 may be considered to have an individual impedance that is favorable to conducting electrical signals of various frequencies. Also, as discussed above, nanowires 204 may have a distribution of sizes and spacings, and the paths may have a distribution of electrical characteristics, with an associated distribution of favored signal frequencies. Furthermore, the impedance of each path is also changed by electrical coupling to other paths. Therefore, the combination of various electrical paths through FO material 201 may cause its impedance to have a magnitude that is substantially linear and a phase that is substantially constant over a bandwidth of input signal frequencies.

For example, FIG. 2 is a graph of the impedance magnitude 305 and impedance phase 310 of an FO material that includes a complex of [NH₂BU₂]ₓ[Pt(Ox)₂] nanowires in a PVA/Pani copolyer, where x is a number between 1 and 2 inclusive. The magnitude 305 and phase 310 are measured against magnitude scale 307 and phase scale 312 respectively. The impedance was measured spectrographically from 10 Hz to 300 KHz. The magnitude of the impedance magnitude 305 is substantially linear. The impedance phase 310 is substantially constant, within the range of −14 to −19 degrees, over the bandwidth.

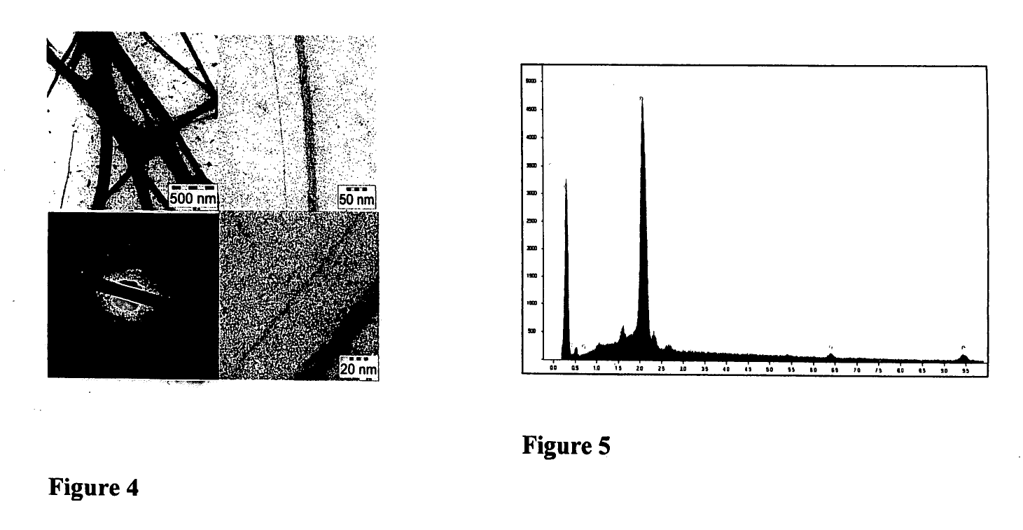

FIG. 3 shows two SEM images of chemically grown nanowires 204, in accordance with the present invention, such as [C₁₀H₁₀N]ₓ[Pt(Ox)₂] nanowires, with x again being a number between 1 and 2 inclusive. FIG. 4 shows three TEM images of such nanowires 204. FIG. 4 includes one showing of an electron diffraction pattern of such nanowires 204. As defined herein, “inorganic” refers to non-carbon components. The word “organic” refers to at least one carbon-containing component.

In an embodiment of the present invention, in order to avoid bundling of individual metal-metal polymer chains (i.e., nanowires) and to control their structure, partially oxidized platinum complexes were prepared with the small cations replaced by large cationic ligands. These ligands are characterized by a localized charge surrounded by an extensive, relatively non-polar organic framework.

In the example of bisoxalatoplatinate complexes, the large ligands fit within the approximately 2.85 Å gap between sequential bisoxalatoplatinate centers, while also forcing neighboring platinum-platinum chains apart through steric hindrance.

In one embodiment, the present invention provides a partially oxidized platinum complex of Formula (III):
[A]ₓ[Pt(L)_{b}Z_{y}] (III)
wherein

A is an aromatic cation;

L is a ligand selected from the group consisting of oxalate, cyano;

Z is an anion;

x is 1, 2 or a non-integer between 1 and 2;

b is an integer 1-4; and

y is 0 or a non-integer between 0 and 2

and all hydrates thereof. Z may include, but is not limited to choride, bromide, fluoride, iodide, or FHF.

In an exemplary embodiment, partially oxidized platinum complexes of Formula III form crystals with a length:width ratio of about 20:1 to about 100:1. However, those skilled in the art would recognize that the nanowires may have other length:width ratios that are convenient to having a desired fractional order impedance of the complex 203. The nanowires may have a distribution of lengths. Additionally, the nanowires may be, but are not limited to being, sized, oriented and positioned so as to form a substantially fractal structure.

In a preferred embodiment, an aromatic cation A may be, but is not limited to, a pyridine, a pyrimidine, a pyridazine, a quinoline, an isoquinoline, a quinazoline, a quinoxaline, or mixtures thereof and may be optionally substituted with 1-4 substituents. Substituents include hydrogen, alkyl, alkoxy, amino, alkyl(N-alkylamino), alkyl-(N,N-dialkylamino), hydroxy, arylalkyl and heteroarylalkyl. In a preferred embodiment, aryl ammonium salts, such as N-methyl isoquinoline, are prepared and utilized to satisfy both of the above discussed prerequisites. These aryl ammonium salts also have the advantages of being readily synthesized and easily modified.

In a more preferred embodiment, L is oxalate, b is 2 and y is 0. In another more preferred embodiment, L is cyano, b is 4 and y is 0. In a most preferred embodiment, Ar is N-methylisoquinoline, L is oxalate, b is 2 and y is 0.

Although partially oxidized platinum complexes have the potential for use in materials applications, their handling and orientation presents certain unique problems. The tendency of some of these complexes to lose waters of hydration can lead to a significant decrease in their conductive properties. Encapsulation of these “nanowires” within a host such as, for example, a polymer matrix was found to reduce the loss of water problem and facilitate sample manipulation and orientation.

The presence of a host that encapsulates the partially oxidized platinum complexes also allows for the incorporation of additional complexes within the host. Examples of such additional complexes could include optically active complexes or charge-transfer complexes. Optically active complexes could include non-linear optical (NLO) complexes.

In an embodiment, the invention provides a composite material comprising the combination of at least one host and at least one partially oxidized platinum complex of formula IV:
[A]ₓ[Pt(L)_{b}Z_{y}] (IV)
wherein

A is a cation;

L is a ligand selected from the group consisting of oxalate, cyano;

Z is an anion;

x is 1, 2 or a non-integer between 1 and 2;

b is an integer 1-4; and y is 0 or a non-integer between 0 and 2,

and all hydrates thereof, and wherein the host is selected from the group consisting of a polymer and a copolymer.

In a preferred embodiment, partially oxidized platinum complexes of Formula IV form crystals with a length:width ratio of about 20:1 to about 100:1.

In a preferred embodiment, the invention provides composite material comprising the combination of a host and a partially oxidized platinum complex of Formula III, wherein the host is selected from the group consisting of a polymer and a copolymer. In a more preferred embodiment, the polymer forms a film with a thickness of about 25 to about 250 microns. In a most preferred embodiment, the polymer is selected from the group consisting of polyvinylalcohol (PVA), polymethyl methacrylate (PMMA) and mixtures thereof. In a more preferred embodiment, the partially oxidized platinum complexes include K_{1.6}[Pt(Ox)₂].2H₂O, Co_{0.8}[Pt(Ox)₂].2H₂O or a mixture thereof.

Polyaniline sulfonic (referred to as PAni) acid was found to be an effective polymer for modifying the electrical properties of the bulk material. Addition of polyaniline sulfonic acid (purchased as a 5% wt/wt solution from Sigma Aldrich) was used to reduce the overall impedance of the PVA polymer, hence a PVA/PAni copolymer.

Humidity has been found to allow ions in the material to become more mobile and move the organic polymer matrix (e.g., PVA/Pani). Thus, the impedance of the material decreases as the relative humidity increases. Humidity has been controlled using saturated salt solutions in a sealed chamber to produce specific humidities. However, more specific control may be obtained using a controlled system of moist and dry air to generate desired humidities.

### EXAMPLES

The nanowire prepared below in Examples 1 and 2 was characterized by scanning electron microscopy (SEM), see FIG. 3, and transmission electron microscopy (TEM), see FIG. 4. As shown in FIG. 5, energy dispersive spectroscopy (EDS) confirmed the platinum content of the nanowire. Selected area electron diffraction (SAED) revealed its microcrystalline nature. Microanalyses were performed by Robertson-Microlit and Maxima Laboratories (Canada) Inc.

For the preparation of a nanowire encapsulated by PVA as shown in Examples 3 and 4, the PVA (M_{w} of about 89,000 to about 98,000) and (NH₄)₂Ce(IV)(NO₃)₆ (99.99%+) were purchased from Aldrich Chemicals and used as supplied. Bisoxalato platinate salts K₂[Pt(Ox)₂].2H₂O and Co[Pt(Ox)₂].6H₂O were prepared by the method of Krogmann et al. in Chem. Ber. 99 (1966) 3402 and by the method of Schultz et al. in Inorg. Chem. 17 (1978) 1313, respectively. These salts were then oxidized in an aqueous solution of (NH₄)₂Ce(IV)(NO₃)₆ to give K_{1.6}[Pt(Ox)₂].2H₂O and Co_{0.8}[Pt(Ox)₂].6H₂O, respectively. The copper-colored, microcrystalline products were washed with chilled water and dried in a dessicator.

In Example 4, [NH₂Bu₂]₂[Pt(Ox)₂].H₂O was prepared via reaction of Ag₂[Pt(Ox)₂].2H₂O with [NH₂Bu₂]Cl in H₂O. The insoluble AgCl was coagulated via gentle warming and filtered off under vacuum. Removal of the solvent gave the yellow solid in good yield. The partially oxidized platinum complex [NH₂Bu₂]ₓ[Pt(Ox)₂] was prepared by chemical oxidation of [NH₂Bu₂]₂[Pt(Ox)₂] with a solution of 0.1M (NH₄)₂Ce(NO₃)₆. PVA (400 mg) was dissolved in H₂O (10 mL) with heating and stirring, once the cloudy solution had turned clear, it was cooled and the PAni was added via pipette to give the PVA/PAni copolymer solution. The polyaniline sulfonic acid was purchased from Sigma-Aldrich as a 5% wt. solution in water). The PVA/Pani copolymer was poured onto the [NH₂BU₂]ₓ[Pt(Ox)₂] material and allowed to dry at room temperature to give a dark, pliable film in which the dispersed [NH₂Bu₂]ₓ[Pt(Ox)₂] material could be seen. Polymer film thicknesses in all Examples 3 and 4 were determined with a micrometer gauge.

### Example 1

### Electrochemical Preparation of [C₁₀H₁₀N]ₓ[Pt(Ox)₂] where C₁₀H₁₀N is N-methyl isoquinoline

C₁₀H₁₀N]₂[Pt(Ox)₂].H₂O was prepared via reaction of Ag₂[Pt(Ox)₂].2H₂O with [C₁₀H₁₀N] in H₂O. The insoluble AgI was coagulated via gentle warming and filtered off under vacuum. Removal of the solvent gave the yellow product in good yield and the composition was confirmed via microanalysis. A saturated solution of [C₁₀H₁₀N]₂[Pt(Ox)₂] (4 mL) was filtered through a 1 μm filter and placed in an electrolytic chamber fitted with gold wire electrodes. A 1.25V voltage was applied and after a 24 hour period, long, dark fibers were observed to have formed. The fibers, which did not undergo decomposition, were dried in air for several days to provide a nanowire. SEM analysis revealed a network of fibers of up to about 1 cm in length and approximately 20 μm or less in diameter, giving an aspect ratio of about 5,000:1 or greater.

### Example 2

### Chemical Preparation of [C₁₀H₁₀N]ₓ[Pt(Ox)₂], where C₁₀H₁₀N is N-methyl isoquinoline

[C₁₀H₁₀N]₂[Pt(Ox)₂] was prepared using any of the reported and well established synthetic procedures. [C₁₀H₁₀N]₂[Pt(Ox)₂] (102.2 mg, 0.155 mmol) was dissolved in 1M CF₃SO₃H (10 mL) with stirring under argon. A solution of 0.1M (NH₄)₂Ce(NO₃)₆ (0.3 mL, 0.03 mmol) was added dropwise and a gray, fibrous material was observed to form. This nanowire product was thoroughly washed with ice-cold water and stored at 5° C. SEM analysis was similar to that reported in the previous example.

### Example 3

### Preparation of PVA Films Containing Potassium and Cobalt Salts of Partially Oxidized Platinum Complexes

PVA (200 mg) was dissolved in water (10 mL) by heating at 75° C. until a clear solution was obtained. The partially oxidized platinum complexes K_{1.6}[Pt(Ox)₂].2H₂O and Co_{0.8}[Pt(Ox)₂].6H₂O were separately dissolve quantities sufficient for the desired composite concentration and were added at room temperature to the PVA solution. This mixture was then poured into a Petri dish and stirred occasionally to ensure homogeneous dispersion of the complexes in the medium. After approximately 3 days, thin composite films were obtained.

### Example 4

### Preparation of PVA Film Containing Dibutyl Ammonium Salt of Partially Oxidized Platinum Complexes

[NH₂Bu₂]₂[Pt(Ox)₂] (100 mg) was dissolved in 1M CF₃SO₃H (15 mL) partially oxidized with 0.1M (NH₄)Ce(IV)(NO₃)₆ to give a mass of fine, coppery, needle-shaped material. The material was poured into a Petri dish and allowed to dry out at room temperature for several days. Approximately 87 mg of nanowire product was collected. PVA (200 mg) was dissolved in water (10 mL) and heated and stirred at approximately 65° C. until all the material dissolved. After cooling, polyaniline sulfonic acid (873 mg) was added to make the polyaniline sulfonic acid concentration approximately 17.9% by weight. The nanowire product [NH₂Bu₂]ₓ[Pt(Ox)₂] was then added and the resulting slurry was allowed to evaporate at room temperature for several days to give a pliable black film in which the needles of [NH₂Bu₂]ₓ[Pt(Ox)₂] were visible.

### Results

The properties of conductivity and the real and imaginary components of capacitance were measured for each of the prepared partially oxidized platinum complexes and for each of the composites (i.e., complexes encapsulated in a host material). It was discovered that their overall physical properties of the composites varied depending upon the orientation of the complexes. In addition, for the complexes in general, electrical properties varied depending on the identity of the cation or cations present and/or the optional anion depicted as Z in Formulae III and IV, which includes Formulae I and II.

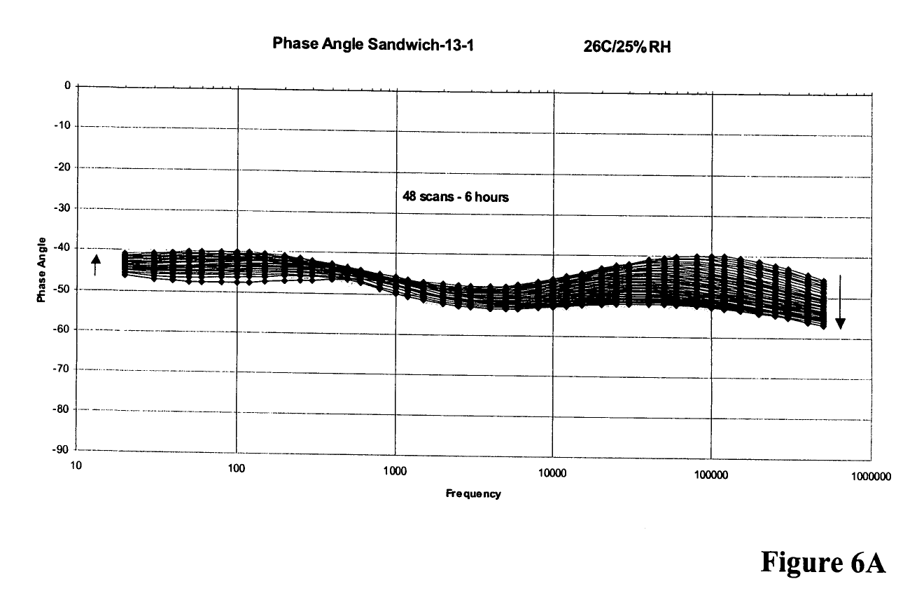

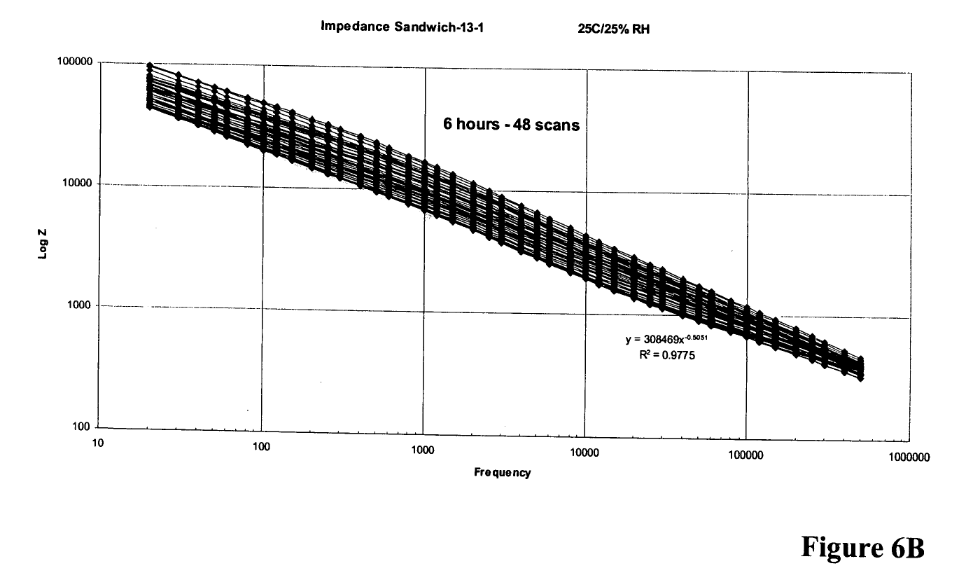

A linear, passive, two-lead electronic device with generalized Warburg impedance can be described in the fractional order impedance, a “fractance,” of the form:

$${Z}_{F} ( f ) = \frac{\vert {Z}_{C} \vert}{{( j \frac{f}{{f}_{C}} )}^{a}} , \qquad ( 1 )$$

where the magnitude of the impedance is Z_{C} ohms at reference frequency f_{C}, α is a non-integer exponent, and \sqrt{−1}. Impedance spectroscopy of a representative fractional order impedance device, i.e., fractor, is shown in FIGS. 6A and 6B. There is some natural “ripple” in the phase over the frequency band of interest. Plus or minus about 10% phase variation over the band does not affect the basic properties described herein. As seen in FIG. 6B, an excellent fit to a power-law function is possible.

The fractional form of Equation 1 holds over the frequency band of interest, at least three decades of frequency. This distinguishes the fractor from approximations of fractance created from networks of discrete conventional integer order elements. At some upper frequency, the impedance is often dominated by parasitic by-pass capacitance due to the electrode layers. The fractance devices will have electrical limitations of voltage, current, and operating temperature, just as with other passive electronic elements.

The form of Equation 1 admits to description of all conventional ideal passive electronic components, e.g., inductors (α=−1), resistors (α=0), and capacitors (α=1). The claims made herein specifically exclude the conventional inductor and resistor (α=−1 and 0) and the class of “lossy” bipolar capacitors with dissipation factors (referred to as “tan δ”) up to 0.3. Also excluded are the unipolar electrolytic capacitors with dissipation factors up to 0.5 as conventionally used as filters.

Fractance can also be written in terms of angular frequency, ω=2πf, notation with τ=1/(2πf_{C}) as

$${Z}_{F} ( ω ) = \frac{\vert {Z}_{C} \vert}{{( j ω τ )}^{a}} , \qquad ( 2 )$$

and Laplace form, with s=jω, as

$${Z}_{F} ( s ) = \frac{\vert {Z}_{C} \vert}{{( s τ )}^{a}} . \qquad ( 3 )$$

In the latter form, it becomes evident that fractance is described by the fractional order integral of order α.

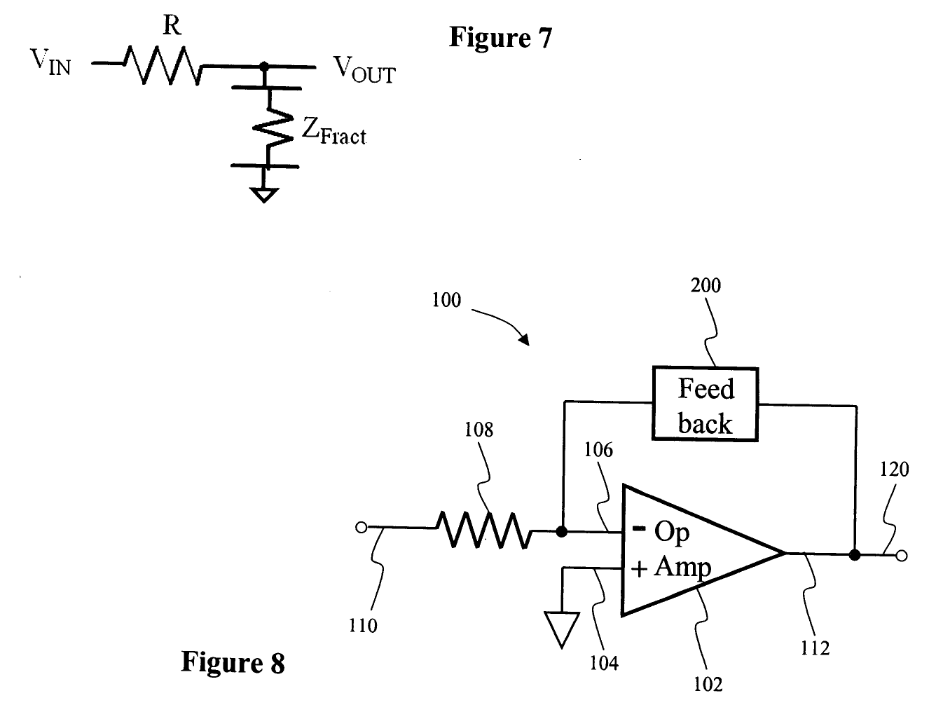

As such, parallel and series arrangements of circuits having fractional order impedance is possible where the algebraic rules for combining impedances into equivalent circuits apply. For example, an example of a low pass filter is shown in FIG. 7 having an output as shown in equation (4).

$$A ( s ) = \frac{{V}_{out} ( s )}{{V}_{i n} ( s )} = \frac{1}{1 + \frac{R}{\vert {Z}_{C} \vert} {( s τ )}^{a}} \qquad ( 4 )$$

Further, electrical elements with FO impedances in conjunction with operational amplifiers can be used to implement FO calculus operations. For example, FIG. 8 shows an exemplary circuit 100 for performing FO integration. Operational amplifier (op-amp) 102 is connected at its positive input 104 to ground potential and at its negative input 106 to a terminal of resistor 108. The other terminal of resistor 108, which has resistance R₁₀₈, is connected to circuit input terminal 110. Op-amp 102 is connected at its output terminal 112 to circuit output terminal 120. Op-amp output terminal 112 is also connected to one terminal of a feedback element that is a pure FO component 200. The other terminal of FO component 200 is connected to op-amp input terminal 106. A pure FO component 200 has the FO impedance as shown in equation (3) above.

The voltage at circuit input terminal 110 is Vᵢₙ, and the voltage at circuit output terminal 120 is Vₒᵤₜ. Therefore, circuit 100 has a transfer function according to equation (4)

$$\frac{{V}_{out}}{{V}_{i n}} = \frac{- \vert {Z}_{c} \vert / {R}_{108}}{{( s τ )}^{a}} \qquad ( 5 )$$

where α is a fraction between zero and one. Circuit 100 is merely exemplary, and those skilled in the art will recognize that fractional order calculus operations may be implemented using other electrical circuits and using other values of impedance order α.

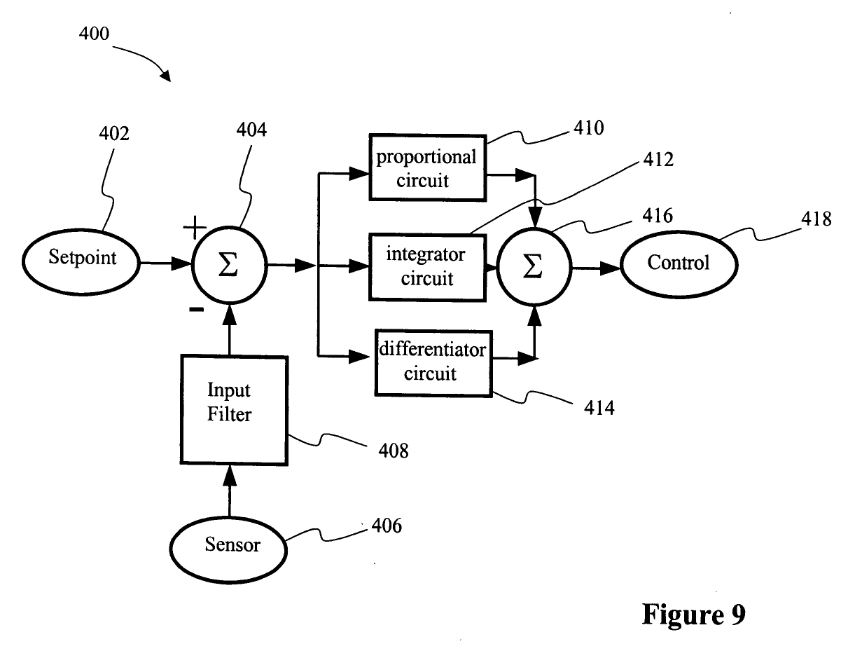

FIG. 9 schematically shows another embodiment of the present invention, which is an exemplary automatic controller 400 that uses FO electrical impedance. Controller 400 includes a setpoint 402 connected to an input summer 404. A plant sensor 406 passes through an input filter 408 to input summer 404. Input summer 404 provides a signal to a proportional circuit 410, an integrator circuit 412 and a differentiator circuit 414. Each of said circuits provides an output signal to output summer 416, which provides control signal 418. Integrator circuit 412 may be a circuit 100 with a transfer function proportional to s^{-α}, such as that shown in FIG. 8. Alternatively, any of proportional circuit 410, integrator circuit 412 and differentiator circuit 414 may be omitted or may be replaced by circuitry that uses FO impedance. For example, differentiator circuit 414 may be a circuit with a transfer function proportional to s^{q} that uses FO impedance to perform FO differentiation.

Of course, FO automatic controllers are not limited to the exemplary circuits of FIGS. 7 to 9 but may be made of various circuitries. Automatic controller 400 may be applied to controlling various processes, such as electrical motor speed, electrical heater operation, and electrical power voltage or current supplies.

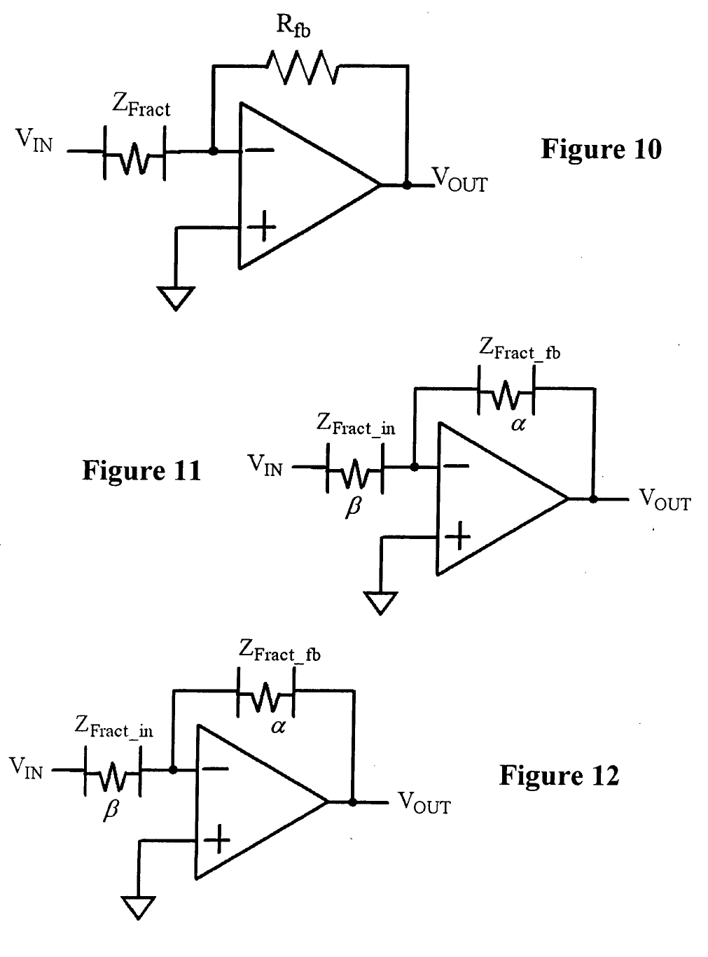

Moreover, placing the fractor in the input position as shown in FIG. 10 can form a fractional order derivative operator, Equation 8.

$$A ( s ) = \frac{{V}_{out} ( s )}{{V}_{i n} ( s )} = - \frac{{R}_{fb}}{{\vert {Z}_{C} \vert}_{i n}} {( τ s )}^{a} \qquad ( 8 )$$

With the fractor, it is therefore possible to create fractional order operators of orders obtained by exponent arithmetic. Given one fractor of order a and another of order β, an operator of order γ=β−α can be created as shown in FIG. 11.

$$A ( s ) = \frac{{V}_{out} ( s )}{{V}_{i n} ( s )} = - \frac{\vert {Z}_{Ca} \vert}{\vert {Z}_{C β} \vert} \frac{{( {τ}_{β} s )}^{β}}{{( {τ}_{a} s )}^{a}} = - \frac{\vert {Z}_{Ca} \vert}{\vert {Z}_{C β} \vert} \frac{1}{{( Ts )}^{a - β}} \qquad ( 9 )$$

Cascading amplifier circuits of the form of FIG. 11 in series allows adding two exponents and subtracting two. The primary limits to the number of cascaded elements are the quality of the operational amplifiers and the phase ripple (phase variation over frequency) of the fractors used in the circuit. Care must be given to operator composition rules of the fractional calculus when cascading amplifiers to form new composite operators.

A proportional plus fractional order integral (PI^{λ}) controller, described by Equation 10, can be formed using the diagram of FIG. 12.

$$A ( s ) = \frac{{V}_{out} ( s )}{{V}_{i n} ( s )} = \frac{{R}_{f}}{{R}_{i}} + \frac{\vert {Z}_{fc} \vert}{{R}_{i}} \frac{1}{{( τ s )}^{λ}} \qquad ( 10 )$$

Summing the outputs of FIGS. 10 and 12, where the two exponents λ and μ need not be the same, can create PI^{λ}D^{μ} controllers. Other configurations allow for implementation of either dependent or independent PI^{λ}D^{μ} controllers, as described, for example, by I. Podlubny, Fractional Differential Equations: An introduction to fractional derivatives, fractional differential equations, to methods of their solutions and some of their applications, Academic Press, San Diego, 1999.

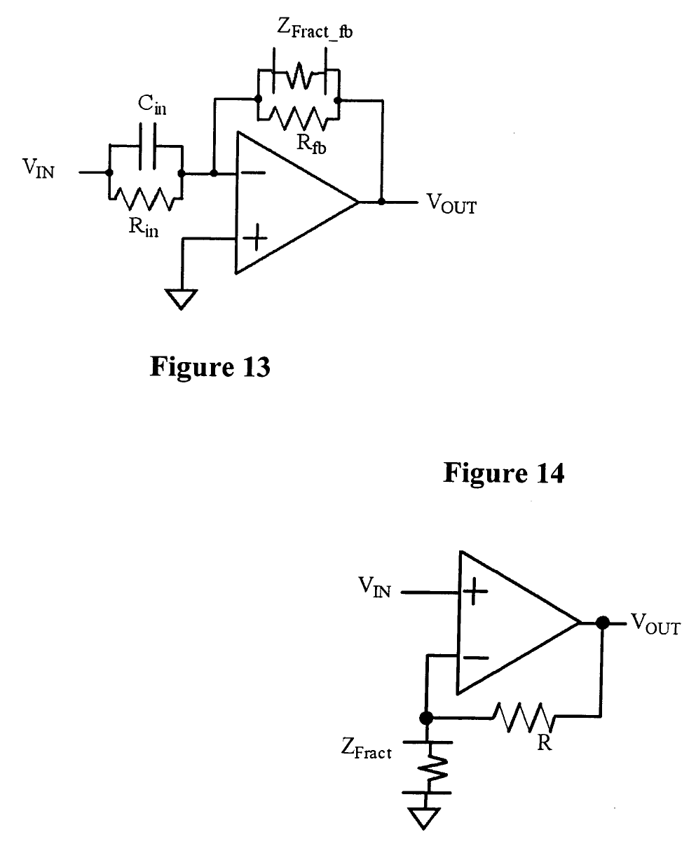

In addition, phase compensation over broad bands is possible. As shown in FIG. 13, lead-lag compensation with limits other than 0 and +/−90 can be achieved.

$$A ( s ) = \frac{{V}_{out} ( s )}{{V}_{i n} ( s )} = \frac{{R}_{fb}}{{R}_{i n}} \frac{1 + {sR}_{i n} {C}_{i n}}{1 + \frac{{R}_{fb}}{\vert {Z}_{C} \vert} {( s τ )}^{α}} = K \frac{1 + {T}_{i n} s}{1 + {( {T}_{fb} s )}^{α}} \qquad ( 11 )$$

When the circuit of FIG. 13 is combined with fractional order integrators and differentiator circuits, almost any phase is available over many decades of frequency. Again, the limitations include the extent of phase ripple over the frequency band of interest and the noise and offset specifications of the operational amplifier.

Positive polarity configurations are also useful. FIG. 14 shows a PD^{μ} control circuit with a response of

$$A ( s ) = \frac{{V}_{out} ( s )}{{V}_{i n} ( s )} = 1 + \frac{R}{\vert {Z}_{C} \vert} {( τ s )}^{μ} . \qquad ( 11 )$$

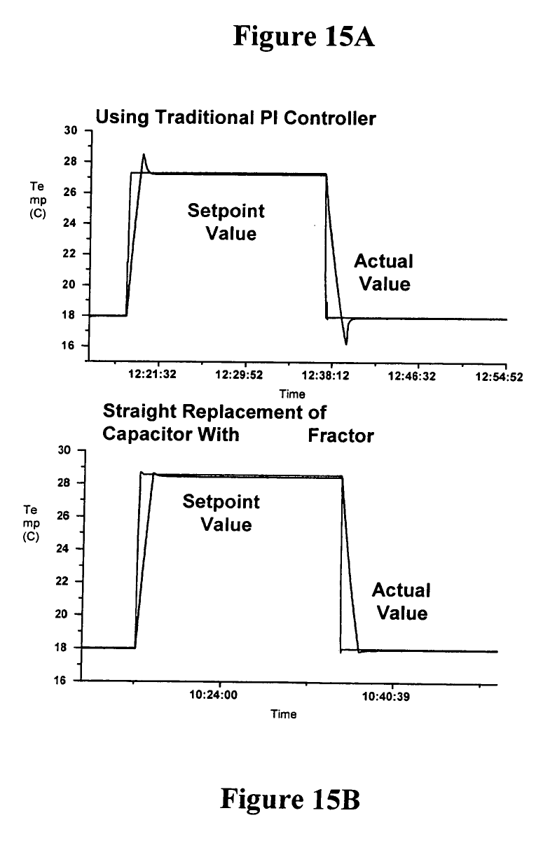

FIGS. 15A and 15B shows temperature control performance obtained with a PI^{λ} controller (FIG. 12), with λ≈0.5, versus a conventional PI controller. Note that the overshoot and time to stable temperature are significantly reduced with the fractional order controller.

It should be apparent that the foregoing circuits are exemplary and numerous other circuits can be achieved in accordance with the present invention.

### Alternative Fractor Configuration

It has been further found that similar results can be obtained with properly designed platinum-free systems. A fractional impedance device, i.e., a fractor, can be constructed from roughened metal (or other conducting material) surfaces held face to face by a spacer. The surfaces may be roughened by sand blasting, bead blasting, chemical etching, lithographic techniques, or other techniques. The space between the plates is filled with electrically conducting polymer doped with acid and containing ionic materials so as to provide multiple pathways and charge carriers for the conduction of electricity. These composite materials possess, on a localized scale, a variety of impedance and capacitance values due to the fractal surface of the roughened metal plates, and a variety of activation barriers for the charge carriers.

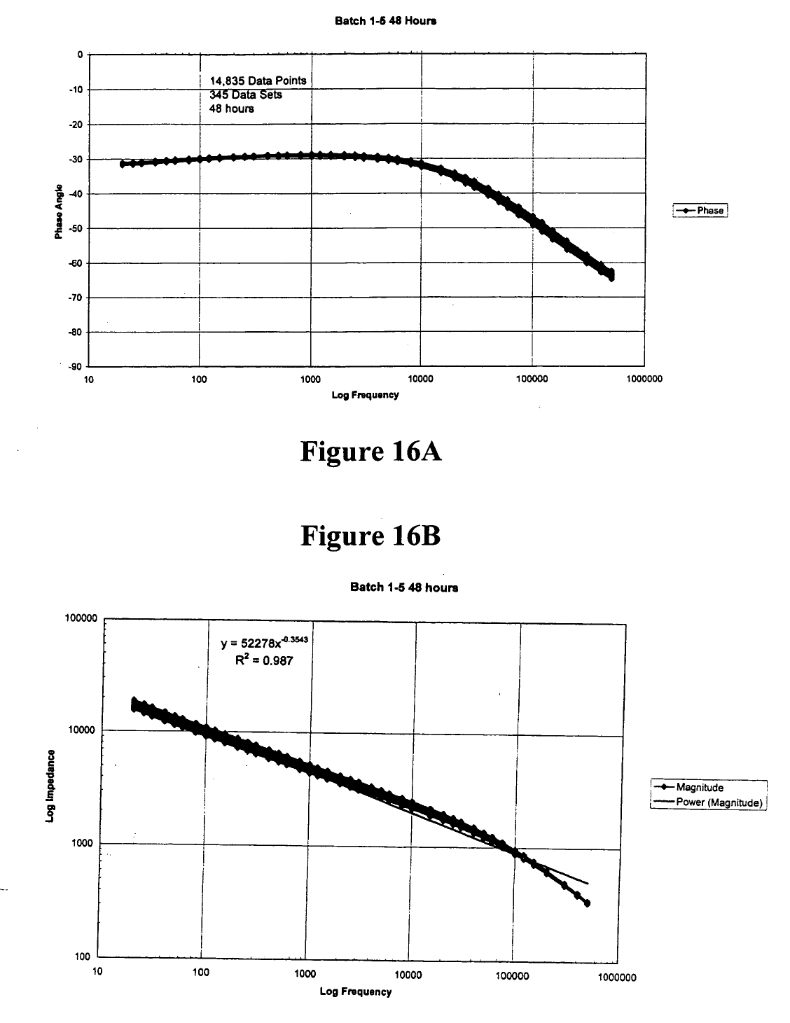

One specific example, but not the only example, of such a system is two square copper plates, roughened by sand or bead blasting, held about 1.0 mm apart containing a solution made from 28 mL water, 28 mL 95% ethanol, 14 mL TEOS, 2 drops of nitric acid, drops of 5% polyaniline sulfate, and 2.805 grams of lithium nitrate. The experimental results from such a configuration are shown in FIGS. 16A and 16B.

Those skilled in the art will appreciate that various modifications can be made in the present invention without departing from the spirit or scope of the invention. Thus, it is intended that the present invention cover the modifications and variations of this invention provided they come within the scope of the appended claims and their equivalents.

We claim:

1. An electrical component comprising a substantially homogeneous impedance material, a first terminal electrically connected to a first part of the impedance material, and a second terminal electrically connected to a second part of the impedance material, wherein the electrical response of the impedance material includes a parameter that can be characterized as a resistive voltage loss and a parameter that can be characterized as a capacitive time delay.

2. An electrical component comprising an impedance material, a first terminal electrically connected to a first part of the impedance material, and a second terminal electrically connected to a second part of the impedance material, wherein the impedance material has an electrical impedance that is proportional to s^{-r}, wherein r is a substantially non-integer real number.

3. The electrical component of claim 2, wherein r is a fraction between 0.1 and 0.9.

4. The electrical component of claim 2, wherein r is a fraction between 0.2 and 0.8.

5. The electrical component of claim 2, wherein the electrical impedance has a magnitude that is substantially linear and a phase that is substantially constant, over a bandwidth of input signal frequencies.

6. The electrical component of claim 5, wherein the bandwidth is from 10 Hz to 300 kHz.

7. The electrical component of claim 6, wherein the phase varies by ±10 degrees or less over the bandwidth.

8. The electrical component of claim 2, wherein the impedance material includes a complex of electrically conductive nanowires.

9. The electrical component of claim 8, wherein the sizes and spacings of the nanowires are interspersed substantially homogeneously through the impedance material.

10. The electrical component of claim 8, wherein the nanowires include a partially oxidized platinum complex.

11. The electrical component of claim 8, wherein the complex of nanowires is encapsulated in a host material.

12. The electrical component of claim 11, wherein the host material has a thickness of between 25 and 250 microns.

13. The electrical component of claim 11, wherein the host material is a polymer, a copolymer, or a combination thereof.

14. The electrical component of claim 8, wherein a first part and a second part of the complex of nanowires are encapsulated in a conductive host material, and wherein a third part of the complex of nanowires is encapsulated in a nonconductive host material.

15. The electrical component of claim 10, wherein the nanowires are a partially oxidized platinum complex of Formula (III):
[A]ₓ[Pt(L)_{b}Z_{y}] (III)
wherein
A is an aromatic cation;
L is a ligand selected from the group consisting of oxalate and cyano;
Z is an anion;
x is 1, 2 or a non-integer between 1 and 2;
b is an integer 1-4; and
y is 0 or a non-integer between 0 and 2;
and all hydrates thereof.

16. A partially oxidized platinum complex of Formula (III):
[A]ₓ[Pt(L)_{b}Z_{y}] (III)
wherein
A is an aromatic cation;
L is a ligand selected from the group consisting of oxalate and cyano;
Z is an anion;
x is 1, 2 or a non-integer between 1 and 2;
b is an integer 1-4; and
y is 0 or a non-integer between 0 and 2;
and all hydrates thereof.

17. The complex according to claim 16, wherein L is oxalate; b is 2; and y is 0.

18. The complex according to claim 16, wherein L is cyano; b is 4; and y is 0.

19. The complex according to claim 16, wherein A is N-methylisoquinoline, L is oxalate; b is 2; and y is 0.

20. The complex according to claim 16, wherein the partial oxidation is done through photo-oxidation.

21. The complex according to claim 16, wherein A is chiral in structure.

22. The complex according to claim 17, wherein A is selected from the group consisting of a pyridine, a pyrimidine, a pyridazine, a quinoline, an isoquinoline, a quinazoline, a quinoxaline and mixtures thereof, and may be optionally substituted with 1-4 substituents.

23. The complex according to claim 22, wherein A is N-methylisoquinoline

24. A composite material comprising the combination of at least one host and at least one partially oxidized platinum complex of Formula IV,
[A]ₓ[Pt(L)_{b}Z_{y}] (IV)
wherein
A is a cation;
L is a ligand selected from the group consisting of oxalate and cyano;
Z is an anion;
x is 1, 2 or a non-integer between 1 and 2;
b is an integer 1-4; and
y is 0 or a non-integer between 0 and 2;
and all hydrates thereof, and
wherein the host is selected from the group consisting of a polymer, a copolymer, and combinations thereof.

25. The composite material according to claim 24, wherein A is NH₂Bu₂.

26. The composite material according to claim 24, wherein the partially oxidized platinum complex includes K_{1.6}[Pt(Ox)₂].2H₂O, Co_{0.8}[Pt(Ox)₂].2H₂O or a mixture thereof.

27. The composite material according to claim 24, wherein A is an aromatic cation.

28. The composite material according to claim 27, wherein the polymer is selected from the group consisting of polyvinylalcohol, polymethyl methacrylate and mixtures thereof.

29. A composite material comprising the combination of at least one host and at least one partially oxidized platinum complex of Formula IV,
[A]ₓ[Pt(L)_{b}Z_{y}] (IV)
wherein
A is a cation;
L is a ligand selected from the group consisting of oxalate and cyano;
Z is an anion;
x is 1, 2 or a non-integer between 1 and 2;
b is an integer 1-4; and
y is 0 or a non-integer between 0 and 2;
and all hydrates thereof, and =ps wherein the host includes sol-gel material.

30. A method of making an electrical component comprising,
providing a first terminal and a second terminal;
providing an impedance material; and
electrically connecting the first and second terminals to the impedance material,
wherein the impedance material has an electrical impedance that is proportional to s^{-r} where r is a substantially non-integer real number.

31. The method of claim 30, wherein the impedance material includes a complex of electrically conductive nanowires.

32. The method of claim 31, wherein the nanowires include partially oxidized platinum complexes.

33. The method of claim 31, wherein the complex of nanowires is encapsulated in a nonconductive host material.

34. The method of claim 32, wherein the nanowires are a partially oxidized platinum complex of Formula (III):
[A]ₓ[Pt(L)_{b}Z_{y}] (III)
wherein
A is an aromatic cation;
L is a ligand selected from the group consisting of oxalate and cyano;
Z is an anion;
x is 1, 2 or a non-integer between 1 and 2;
b is an integer 1-4; and
y is 0 or a non-integer between 0 and 2;
and all hydrates thereof.

35. An electrical circuit for forming an integration signal comprising,
an operational amplifier with a negative input terminal, a positive input terminal, and an output terminal;
an input resistor connected between a circuit input terminal and the negative input terminal; and
a feedback element connected between the output terminal and one input terminal of the operational amplifier, wherein the feedback element includes a single component that has a fractional order impedance.

36. An automatic control circuit comprising,
a proportional circuit that outputs a signal that is proportional to an error signal;
an integration circuit that uses a single component that has a fractional order impedance in generating a signal that is proportional to the integer of the error signal.

37. The automatic control circuit of claim 36, further comprising a differentiator circuit that uses a single component that has a fractional order impedance in generating a signal that is proportional to the derivative of the error signal.

38. An electrical circuit comprising:
an operational amplifier with a negative input terminal, a positive input terminal, and an output terminal;
an input impedance connected between a circuit input terminal and the negative input terminal; and
a feedback element connected between the output terminal and one input terminal of the operational amplifier, wherein at least one of the input impedance and the feedback element includes a component having a fractional order impedance.

39. An electrical component comprising first and second conducting portions having opposing surfaces separated by a distance, wherein the opposing surfaces have a roughness so that the impedance between the first and second conducting portions is proportional to s^{-r}, wherein r is a substantially non-integer real number.

40. An electrical circuit comprising a fractional order impedance device as substantially shown and described.
